(19) United States
(12) Patent Application Publication
(10) Pub. No.: US 2025/0306157 A1
(43) Pub. Date: Oct. 2, 2025

(54) Remote Electronic Field Monitor

(71) Applicants: Adam A. Suleske, Culpeper, VA (US); Corey D. Vyhlidal, Locust Grove, VA (US)

(72) Inventors: Adam A. Suleske, Culpeper, VA (US); Corey D. Vyhlidal, Locust Grove, VA (US)

(73) Assignee: United States of America, as represented by the Secretary of the Navy, Arlington, VA (US)

(21) Appl. No.: 18/621,569

(22) Filed: Mar. 29, 2024

(51) Int. Cl. G01R 35/00; G01R 29/08

(52) U.S. Cl. CPC G01R 35/005; G01R 29/0871; G01R 29/0878

(57) ABSTRACT

An electric field probe including a power detector to convert an amplitude of the of an electric field into an analog voltage, a voltage controlled oscillator (VCO) creating a frequency modulated (FM) signal corresponding to an electric field based on the analog voltage, and a microwave amplifier to amplify the FM signal.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The present application relates to electric field measurement devices and systems, and more specifically to a wireless electric field measurement system designed to overcome limitations associated with traditional wired electric field measurement methods.

Traditional electric field measurement techniques involve the use of specialized, expensive equipment, including cables and probes that can cost upwards of $7,000, weigh several pounds, and are difficult to attach to moving or airborne devices due to their wired configurations. These setups require extensive calibration for each component, such as cables, RF attenuators, and connectors, which is time consuming and prone to errors due to potential loose connections. The calibration process itself necessitates the use of a vector network analyzer, which can cost up to $600,000. Moreover, the reliance on oscilloscopes limits the number of simultaneous measurements, inhibiting effective measurement in dynamic environments and leading to significant uncertainties in electric field measurements.

### SUMMARY

The present invention introduces a novel wireless electric field measurement device and system that addresses and overcomes the limitations of traditional methods. Comprising an electric field probe and a ground station, this innovative system simplifies the measurement process, enhances mobility, and significantly reduces costs and potential for measurement errors.

The objectives of the present application include; 1) eliminating the need for expensive, heavy, and cumbersome equipment in electric field measurements; 2) providing a cost-effective solution capable of accurate measurements over distances ranging from meters to kilometers without additional hardware; 3) facilitating electric field measurements in dynamic environments, including moving vehicles or airborne platforms; 4) reducing setup complexity and minimizing points of failure, thereby enhancing reliability and accuracy; 5) enabling comprehensive electromagnetic environment analysis, including multi-path and electric field anomalies, through mobility and ease of use; and 6) significantly lowering the financial and time costs associated with equipment replacement in the event of damage.

In one embodiment, an electric field probe is disclosed. The electric field probe includes a power detector to convert an amplitude of an electric field into an analog voltage, and a voltage controlled oscillator (VCO) generating a frequency modulated (FM) signal based on the analog voltage. In a further embodiment, the electric field probe further includes a microwave amplifier to amplify the FM signal. In a further embodiment, the electric field probe further includes a receiving antenna to sense the electric field and a transmit antenna to transmit the FM signal. In a further embodiment, the electric field probe further includes a microwave amplifier to amplify the VCO output. In a further embodiment, the electric field probe further includes an antenna to receive the frequency modulated (FM) signal, a limiting amplifier to standardize the amplitude of received signals, a second VCO provides a reference frequency that is identical to the first VCO, a mixer to derive a signal indicative of electric field changes based on the reference frequency from the second VCO and the standardized amplitude signal from the limiting amplifier, and a low pass filter to convert said signal back into an amplitude modulated signal that preserves the original signal amplitude pulse parameter information.

In another embodiment, an electric field measurement system is disclosed. In a further embodiment, the system includes an electric field probe a ground station. The electric field probe transmits the FM signal and the ground station receives the signal. In a further embodiment, the system further includes a power detector to convert electric field strength into an analog voltage, a voltage controlled oscillator (VCO) that adjusts its output frequency based on said analog voltage, and an antenna to transmit a frequency modulated (FM) signal corresponding to the electric field. In a further embodiment, the electric field probe is of a size not exceeding 2-3 cubic inches, facilitating deployment in dynamic environments including, but not limited to, moving vehicles and airborne platforms. In a further embodiment, the need for extensive cabling and associated calibration efforts, thereby reducing setup time and potential for measurement errors due to loose connections. In a further embodiment, the system can be operated over any distance that the FM signal can be received. In a further embodiment, the ground station output is directly proportional to the amplitude of the electric field measured by the electric field probe, enabling accurate quantification of electric field characteristics including magnitude, pulse width, and pulse repetition frequency.

In another embodiment, a method of measuring electric fields is disclosed. The method includes capturing electric field data, generating an analog voltage based on the electric field data, and converting the analog voltage to a frequency modulated (FM) signal. In a further embodiment, the method further includes transmitting the FM signal to a ground station, and processing the FM signal to produce an output directly proportional to the amplitude of the original electric field while preserving temporal data. In a further embodiment, the FM signal is wirelessly transmitted to the ground station. In a further embodiment, the method further includes applying a calibration curve to determine the electric field data. a further embodiment, the method further includes wherein an analog to digital converter applies the calibration curve. a further embodiment, the method further includes the method enables effective measurement of electromagnetic interference patterns, including multi-path and electric field anomalies, in a variety of environments by virtue of its portability and dynamic deployment capabilities.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is a conceptual view of the electric field measurement system 100;

FIG. 2 is a conceptual view of the electric field probe 101;

FIG. 3 is a conceptual view of the ground station 103; and

FIGS. 4A-B are a flow chart of the disclosed method.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

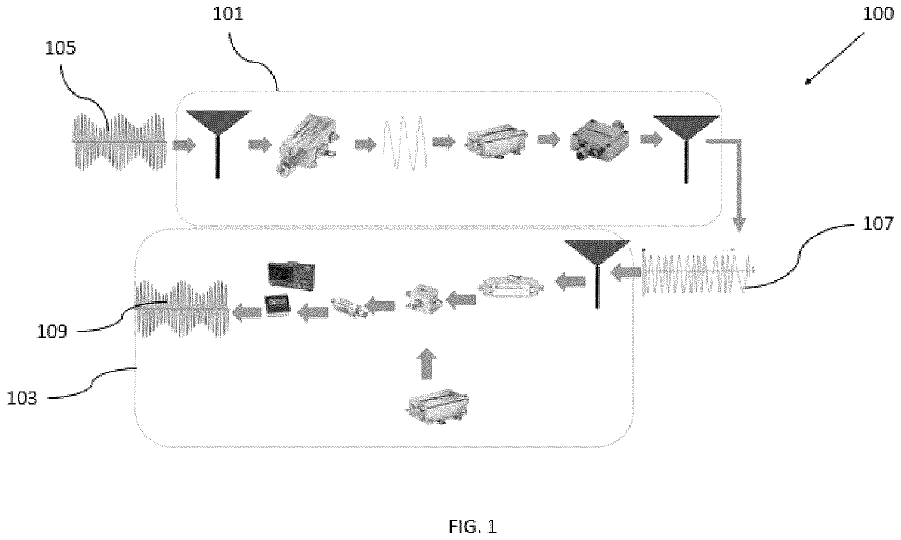

FIG. 1 shows a conceptual view of the electric field measurement system 100. The system 100 consists of an electric field probe 101 and a ground station 103. The field probe 101 captures electric field information 105 and converts it into a frequency-modulated (FM) signal 107 and transmits it to the ground station 103. The ground station 103 processes the FM signal 107 to derive an amplitude-modulated (AM) signal 109 that represents the original electric field's magnitude and any pulse characteristics other than frequency.

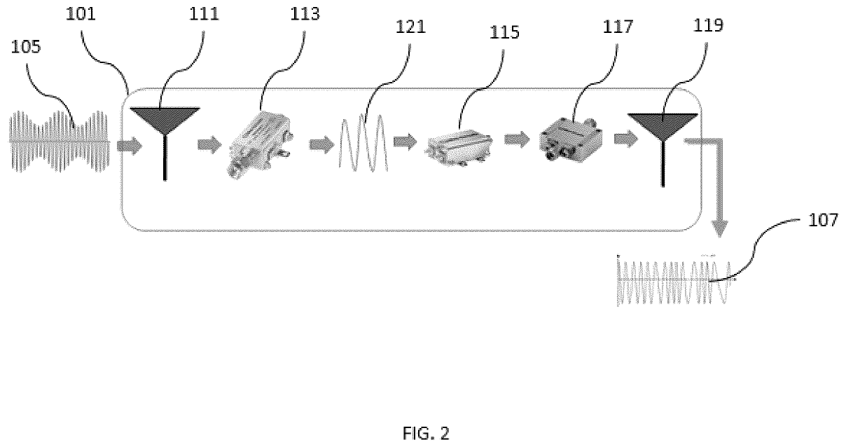

FIG. 2 shows a conceptual view of the electric field probe 101. The probe 101 includes a receive antenna 111, a power detector 113, a voltage controlled oscillator (VCO) 115, an amplifier 117, and a transmit antenna 119. The probe 101 captures electric field information via the receive antenna 111. In turn, the power detector 113 turns the field's amplitude into an analog voltage 121. The higher the electric field, the higher the analog voltage 121. The magnitude of the change in electric field (from no electric field, to high strength electric field) creates a change (swing) in the analog output of the power detector 113. The analog voltage 121 from the power detector 113 is then connected to “tuning voltage” pin (not shown) of the VCO 115. As the analog voltage 121 from the power detector 113 swings from 0 to a higher voltage, the input to the VCO 115 swings, thus making the output of the VCO 115 swing from a low frequency, to a higher frequency. Accordingly, as electric field 105 increases, the frequency from the VCO 115 changes proportionally. This configuration of components effectively takes an incident amplitude modulated (AM) electric field and creates a frequency modulated (FM) signal. The FM signal is then directed into an amplifier 117 which boosts the strength of the signal and transmits this new FM signal 107 out of an antenna 119 and makes it available for receiving by an appropriate ground station. As a result of this signal conditioning method, the RF spectrum of the electric field is lost, however, the pulse width, pulse repetition frequency, and amplitude are preserved.

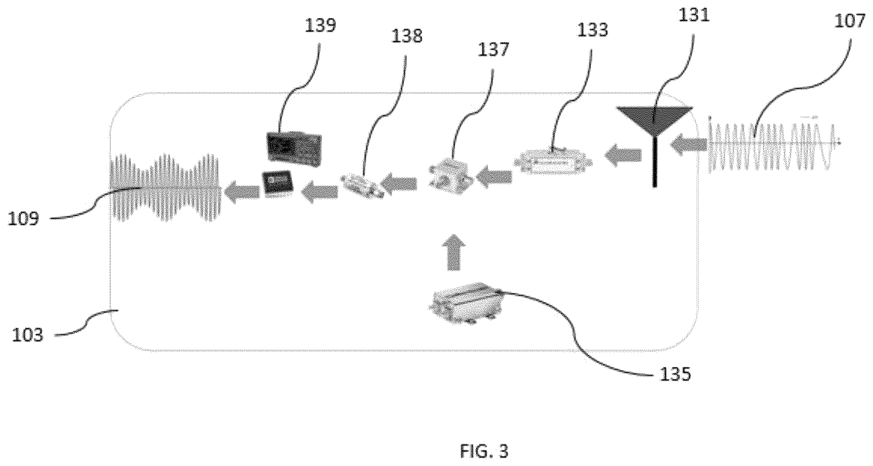

FIG. 3 shows a conceptual view of the ground station 103. The ground station developed consists of a receiving antenna 131, a second VCO, a limiting amplifier 133, and a mixer 137. The antenna 131 attached to the ground station 103 receives the signal 107 sent out from the electric field probe 101 and passes the signal to a limiting amplifier. The limiting amplifier modifies the received signal 107, which may be either small or large, and creates an output that has a constant, known, amplitude. With this constant amplitude, the need to know the distance between the transmitter and receiver becomes unnecessary, because the output of the limiting amplifier 135 is always the same amplitude.

By transforming the amplitude modulated (AM) signal to a frequency modulated (FM) signal, the transmission distance is not relevant because any degradation in the amplitude of the signal can be overcome with different antennas and amplifiers—the information content is preserved in the frequency modulation. In a standard cable setup, signal degradation can become so large that even with physical connections such as cables, the signal can be lost due to amplitude degradation-again, this degradation is overcome by using the FM signal. AM signals are partially recoverable over long distances, however FM signals are fully recoverable over long distances.

Only the frequency of the output changes with respect to the signal 107 received from the electric field probe 101. Then the ground control station 103 routes this signal to the mixer 137.

The mixer 137 includes two inputs and one output. One input receives the signal from the limiting amplifier, which is the signal 107 from the electric field probe 101. The second input is fed from the second VCO. The signal from the second VCO 135 is set to a specific frequency that matches the output frequency of the electric field probe 101 when the probe is not in an electromagnetic environment. The mixer 137 then mixes the signals from the second VCO 135 and the limiting amplifier 133. The result of this mixing yields the frequency difference between the two signals effectively outputting only the baseband signal. The frequency swing of the baseband signal is directly proportional to the change in the electric field that the electric field probe is measuring. The mixer 137 outputs a frequency modulated (FM) signal. A low pass filter 138, either digital or mechanical removes the high frequency image generated by the mixer 137 and leaves only the baseband signal. The derivative of this signal is taken which then takes the constant amplitude FM signal and generates an AM signal proportionate to the amplitude of the original signal incident on the field probe. Finally, the envelope of the received signal is calculated providing amplitude, pulse repetition rate, and pulse width information. This envelope is essentially the “outline” of what the signal packet looks like (this could be a pulsed signal or a continuous wave signal), meaning, that the amplitude is preserved, as well as all pulse parameter data. Thus, the ground control station provides an amplitude-modulated (AM) signal 109 that is directly proportional to the amplitude of the original signal 105 received by the electric field probe 101, as well as any pulse parameter data. In other words, we now know the amplitude of any RF/microwaves incident on the electric field probe 101, as well as any pulse parameter data such as magnitude, pulse width, and pulse repetition frequency of any signal 105 received by the electric field probe 101. All of the original data is preserved with the exception of the frequency content of RF/microwaves that are incident on the electric field probe 101.

The output of the ground station (electric field magnitude, pulse width, and pulse repetition frequency) are then measured using an analog-to-digital converter 139. The analog-to-digital converter 139 may be inside or outside of the ground station 103. A calibration curve of the field probe is then applied to this oscilloscope measurement, which yields the incident electric field on the electric field probe 101. This measurement may be made by an oscilloscope or a significantly less expensive analog-to-digital converter.

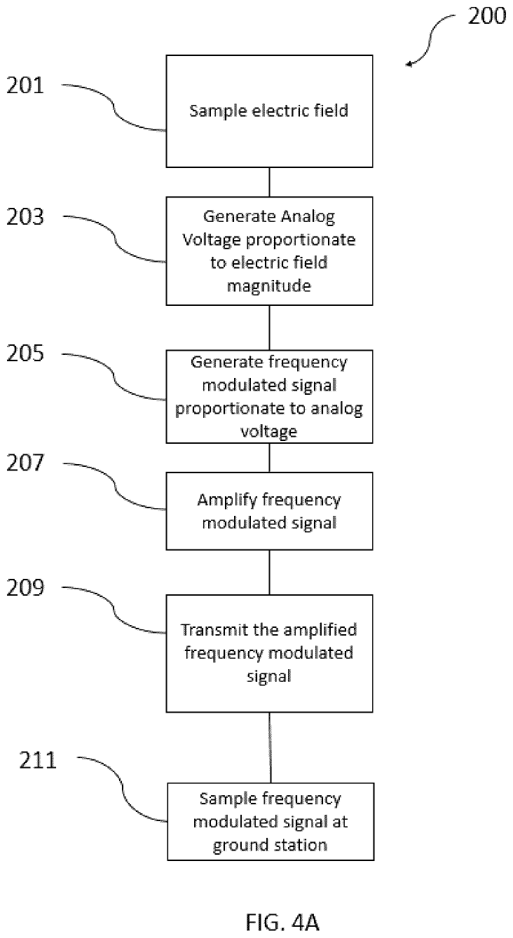

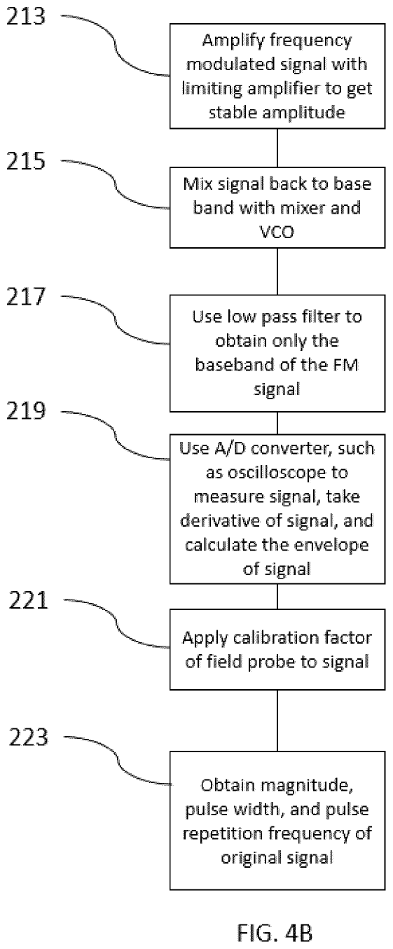

FIGS. 4A-B are a flow chart of the disclosed method 200. In block 201, an electric field probe (as described above) samples an electric field 105 using an antenna 111. This field 105 is an Amplitude Modulated R/F Signal Microwave signal. In block 203, an analog voltage proportional to the electric field magnitude is generated. In the embodiment disclosed the analog voltage is generated by a power detector. In block 205, a frequency modulated (FM) signal proportional to the analog voltage is generated. In block 207, the FM signal is amplified. In block 209, the amplified FM signal is transmitted. In block 211, a ground station samples the FM signal. The method continues in FIG. 4B. In block 213, the FM signal is amplified with a limiting amplifier to produce a stable amplitude. In block 215, the signal from block 213 is mixed to a base band with a mixer and a VCO. In block 217, a low pass filter is used to obtain only the baseband of the FM signal. In block 219, a derivative of the signal is taken and the envelope of the signal is calculated by an A/D converter. The A/D converter may be an oscilloscope or a much less expensive A/D converter. In block 221, a calibration factor of the field probe is applied to the signal. In block 223, the magnitude, pulse width, and pulse repetition frequency of the original signal is obtained.

While certain features of the embodiments of the invention have been illustrated as described herein, many modifications, substitutions, changes, and equivalents will now occur to those skilled in the art. It is, therefore, to be understood that the appended claims are intended to cover all such modifications and changes as fall within the true spirit of the embodiments.

What is claimed is:

1. An electric field probe comprising:
a power detector to convert an amplitude of an electric field into an analog voltage; and
a voltage controlled oscillator (VCO) generating a frequency modulated (FM) signal based on the analog voltage.

2. The electric field probe of claim 1, further comprising:
a microwave amplifier to amplify the FM signal.

3. The electric field probe of claim 1, further comprising:
a receiving antenna to sense the electric field; and
a transmit antenna to transmit the FM signal.

4. The electric field probe of claim 1, wherein the electric field probe further comprises:
a power detector to convert electric field strength into an analog voltage;
a voltage controlled oscillator (VCO) that adjusts its output frequency based on said analog voltage; and
an antenna to transmit a frequency modulated (FM) signal corresponding to the electric field.

5. The electric field probe of claim 1, wherein the electric field probe further comprises:
a microwave amplifier to amplify the VCO output.

6. An electric field measurement system, comprising:
an electric field probe;
a ground station;
wherein the electric field probe transmits the FM signal and the ground station receives the signal.

7. The system of claim 6, wherein the ground station further comprises:
an antenna to receive the frequency modulated (FM) signal;
a limiting amplifier to standardize the amplitude of received signals;
a second VCO provides a reference frequency that is identical to the first VCO;
a mixer to derive a signal indicative of electric field changes based on the reference frequency from the second VCO and the standardized amplitude signal from the limiting amplifier; and
a low pass filter to convert said signal back into an amplitude modulated signal that preserves the original signal amplitude pulse parameter information.

8. The system of claim 6, wherein the electric field probe is of a size not exceeding 2-3 cubic inches, facilitating deployment in dynamic environments including, but not limited to, moving vehicles and airborne platforms.

9. The system of claim 6, further characterized by its wireless operation, eliminating the need for extensive cabling and associated calibration efforts, thereby reducing setup time and potential for measurement errors due to loose connections.

10. The system of claim 6, wherein the system can be operated over any distance that the FM signal can be received.

11. The system of claim 6, wherein the ground station output is directly proportional to the amplitude of the electric field measured by the electric field probe, enabling accurate quantification of electric field characteristics including magnitude, pulse width, and pulse repetition frequency.

12. A method of measuring electric fields comprising:
capturing electric field data;
generating an analog voltage based on the electric field data; and
converting the analog voltage to a frequency modulated (FM) signal.

13. The method of claim 12, the method further comprising:
transmitting the FM signal to a ground station; and
processing the FM signal to produce an output directly proportional to the amplitude of the original electric field while preserving temporal data.

14. The method of claim 12, wherein the FM signal is wirelessly transmitted to the ground station.

15. The method of claim 12, further comprising applying a calibration curve to determine the electric field data.

16. The method of claim 15, wherein an analog to digital converter applies the calibration curve.

17. The method of claim 12, wherein the method enables effective measurement of electromagnetic interference patterns, including multi-path and electric field anomalies, in a variety of environments by virtue of its portability and dynamic deployment capabilities.
